(19) United States
(12) Patent Application Publication
(10) Pub. No.: US 2004/0085743 A1
(43) Pub. Date: May 6, 2004

(54) Tape carrier package

(76) Inventor: Yih-Cherng Juang, Yuanlin Chen (TW)

Correspondence Address: J.C. Patents, Suite 250, 4 Venture, Irvine, CA, 92618, US

(21) Appl. No.: 10/695,017

(22) Filed: Oct. 27, 2003

Related U.S. Application Data
(62) Division of application No. 09/967,710, filed on Sep. 27, 2001.

(30) Foreign Application Priority Data
Aug. 29, 2001 (TW) 90121269

(51) Int. Cl. H05K 5/02; H05K 7/18; H01L 23/48; H01L 23/52; G01R 31/02

(52) U.S. Cl. 361/813; 324/763; 257/690

(57) ABSTRACT

A tape carrier package has a chip, a tape carrier and sealing material. The chip has an active surface on which a plurality of bump electrodes are centrally arranged in two rows. The tape carrier has a device hole smaller than the chip, and has a plurality of leads each of which is divided into inner lead and outer lead. The inner leads are routed inward the center of the device hole and connected to the bump electrodes, respectively. The sealing material encapsulates the active surface of the chip and the inner leads, with the outer leads being exposed.

### CROSS-REFERENCE TO RELATED APPLICATION

This application claims the priority benefit of Taiwan application serial no. 90121269, filed Aug. 29, 2001.

### BACKGROUND OF THE INVENTION

1. Field of the Invention

The present invention relates to a tape carrier package. More specifically, the present invention relates to a package having a device hole smaller than a chip.

2. Description of the Related Art

Currently, various portable electronic equipments such as note book PC, cell phone, electronic dictionary, personal digital assistant are widely used. For such a portable electronic equipment, it is necessary to decrease the dimension and weight of every part of the equipment. As the manufacture technology improves, the sale price for the liquid crystal display is increasing popular and the liquid crystal display becomes essential for a portable electronic device

A tape carrier package is widely used for a conventional liquid crystal display driver chip. An insulating film is used as a base tape of the tape carrier. After the desired patterns are defined, a copper foil layer is attached onto the film. Inner leads and outer leads are defined by etching the copper coil layer. Moreover, it is necessary to form bump electrodes on bonding pads of an active surface of a chip. By using thermal pressing, the inner leads are bonded to the bump electrodes on the chip. A sealing material is used to encapsulate the active surface of the chip and the inner leads, with the outer leads being exposed. However, in a conventional tape carrier package, after thermal pressing, the inner routed inward the chip has to be extended in consideration of bending stress at a bent portion.

A conventional tape carrier package is described below by referring to FIGS. 1-3. FIG. 1 is a schematic top view showing a conventional tape carrier package with no sealing material. FIG. 2 is a partially enlarged view of FIG. 1. FIG. 3 is a cross sectional view of FIG. 1 along line II-II. In general, the tape carrier includes a plurality of package units. Here, only one package unit is illustrated for exemplification. The tape carrier 108 has a device hole 110 and a plurality of leads 112. Further, the tape carrier 108 has a plurality of sprocket hole 122, an alignment mark 124 and slit 120. Each lead 112 is divided into an inner lead 112a and an outer lead 112b, as shown in FIG. 2.

A plurality of bonding pads (not shown) are arranged along a periphery of a conventional chip 102. A corresponding bump electrode 106 is formed on the bonding pad (not shown) on the active surface 102a of the chip 102. The inner lead 112a of the tape carrier 108 is bonded to bump electrode 106 of the chip 102 by thermal pressing.

However, deformation of the inner lead 112a tends to occur during thermal pressing. In order to prevent the inner lead 112a from being deforming, the inner lead portion between the device hole 110 and the bump electrode 106 has to be bent with a bent angle 104 from the horizontal line.

If the bent angle 104 is too large, the inner lead 112 is liable to crack due to the bending stress during packaging. Therefore, the device hole 110 has to be larger than the chip 102 in the prior art, with about 200 micron of a distance from an edge of the device hole 110 to an edge of the chip 102. The bump electrode 106 is separated from an edge of the adjacent chip 102 with a distance of about 50 micron. That is, the total length d1 of the inner lead extended from the edge of the device hole 110 to the bump electrode 106, including the length of the bump electrode 106, is about 330 micron which is the presently minimal value under the acceptable condition.

For the above-discussed reasons, the length and width of the device hole 110 are larger the corresponding length and width of the chip 102 by about 400 micron. This not only wastes the space of the tape carrier, but also decreases in the wiring areas 121, 123 on the tape carrier, such that a compact, thin and lightweight liquid crystal display is difficult to be realized.

Further, since the more the output signal electrodes of the chip increase, the chip becomes longer and narrower. In packaging, any defect or crack on the appearance of the chip tends to adversely effluence the performance of the chip. It is not obvious to detect the defects on the chip, such that the reliability of the product may be lowered.

### SUMMARY OF THE INVENTION

In one aspect of the present invention, a tape carrier package which reduced the package size is provided.

In other aspect of the present invention, a tape carrier package which can meet the lightweight and compact requirement for a liquid crystal display is provided.

In another aspect of the present invention, a chip on which defects can be detected, if any, after sealing the chip.

In order accomplish the above objects, a tape carrier package having a chip, a tape carrier and sealing material is provided. The chip has an active surface on which a plurality of bump electrodes are centrally arranged in two rows. The tape carrier has a device hole smaller than the chip, and has a plurality of leads each of which is divided into inner lead and outer lead. The inner leads are routed inward the center of the device hole and connected to the bump electrodes, respectively. The sealing material encapsulates the active surface of the chip and the inner leads, with the outer leads being exposed.

The present invention further provides a chip suitable for electrically detecting edge defects thereof after packaging. The chip comprises an active surface, a plurality of bump electrodes, two test bumps, and a test circuit. The bump electrodes are centrally arranged in two rows on the active surface. The test bumps are located at each end of the two rows of the bump electrodes. The test circuit is around the edge of the chip on the active surface, wherein ends of the test circuit are electrically connected to the test bumps, respectively. And, two of the leads are connected to the two test bumps, respectively.

By taking one advantage of the centrally-arranged-in-two-row bump electrodes which increase the extended length of the inner lead desired for reduce the bent angle of the inner lead, a compact lightweight tape carrier package having smaller device hole, increased wiring area on the tape carrier and decreased length of tape carrier can be realized.

By providing two test bumps respectively located at ends of the two rows of the bump electrodes, and a test circuit on the active surface around the edge of the chip, any defect at the edge of the chip can be detected by electrically connecting the ends of the test circuit to the two test bumps. Thereby, the reliability of the product can be improved.

### BRIEF DESCRIPTION OF THE DRAWINGS

It is to be understood that both the foregoing general description and the following detailed description are exemplary, and are intended to provide further explanation of the invention as claimed.

The accompanying drawings are included to provide a further understanding of the invention, and are incorporated in and constitute a part of this specification. The drawings illustrate embodiments of the invention and, together with the description, serve to explain the principle of the invention. In the drawings,

FIG. 1 is a schematic top view showing a conventional tape carrier package with no sealing material;

FIG. 2 is a partially enlarged view of FIG. 1;

FIG. 3 is a cross sectional view of FIG. 1 along line II-II;

FIG. 4 is a schematic top view showing a tape carrier package according to a first preferred embodiment of the present invention, with no sealing material;

FIG. 5 is a partially enlarged view of region 226 of FIG. 4;

FIG. 6 is a cross sectional view of FIG. 4 along line I-I;

FIG. 7 is a schematic, cross sectional view showing the tape carrier package of FIG. 4 after sealing; and

FIG. 8 is a schematic top view showing a second preferred embodiment of the present invention.

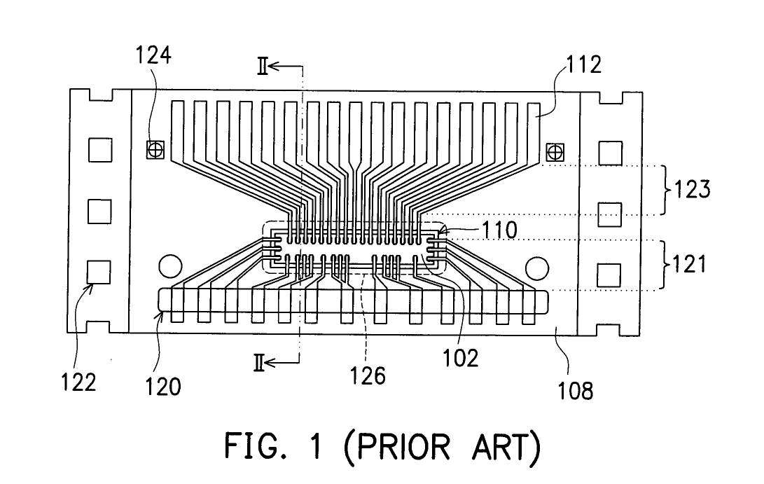

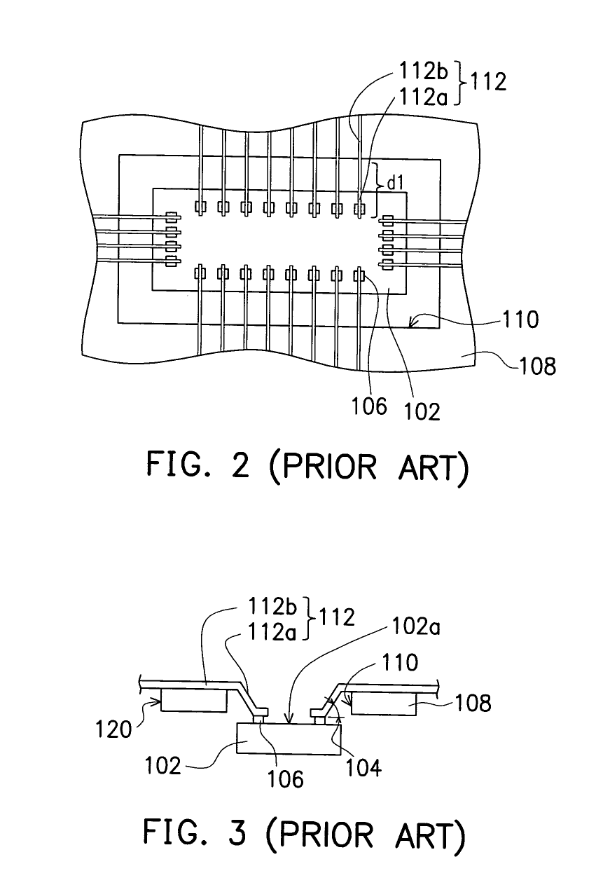

### DESCIPTION OF THE PREFERRED EMBODIMENT

Reference will now be made in detail to the present preferred embodiments of the invention, examples of which are illustrated in the accompanying drawings. Whenever possible, the same reference numbers are used in the drawings and the description to refer to the same or like parts.

First Preferred Embondiment

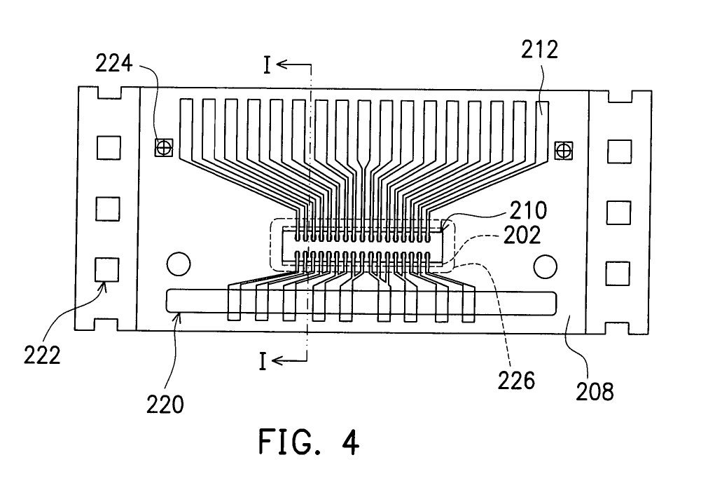

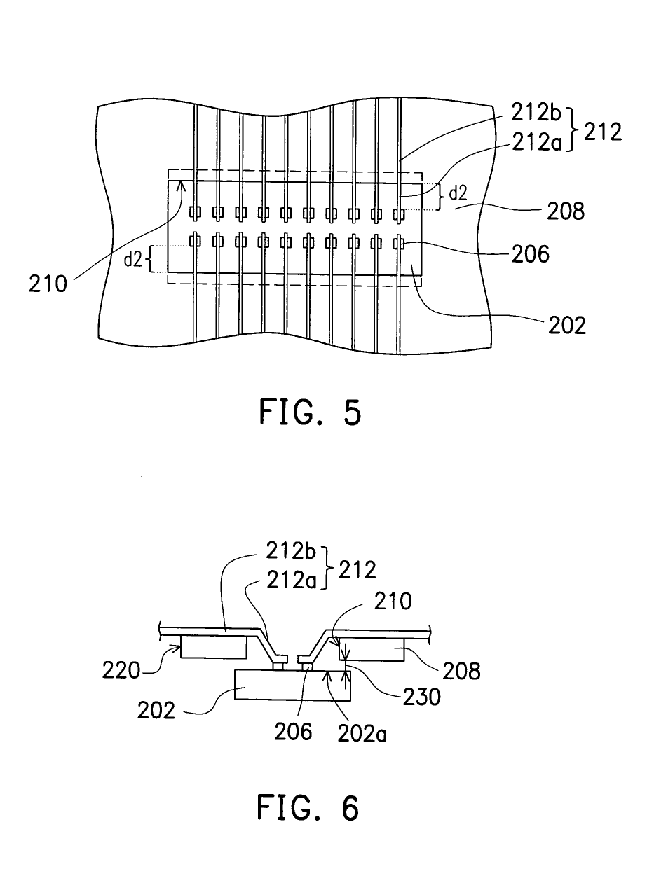

FIG. 4 is a schematic top view showing a tape carrier package according to a first preferred embodiment of the present invention, with no sealing material is shown. FIG. 5 is a partially enlarged view of area 226 in FIG. 4. FIG. 6 is a cross sectional view of FIG. 4 taken along a line I-I.

Chip 202 has an active surface 202a. Using a bump formation process, a plurality of bump electrodes 206 are provided in two rows on a central region of the active surface 202a.

On a tape carrier 208, a plurality of package units (not totally shown in figures) are usually provided. Here, only a package unit is exemplified for brief illustration. The tape carrier 208 has a device hole 210 and a plurality of leads 212. An area of the device hole 210 is smaller than that of the chip 202. Each of the leads 212 has an inner lead 212a and outer lead 212b, as shown in FIG. 5. The tape carrier 208 further has a plurality of sprocket holes 222, an alignment mark 224 and a slit 220. The inner lead 212a is routed toward the center of the device hole 210. The inner lead 212a is electrically connected to the bump electrode 206 by a thermal pressing process.

In the direction for the inner lead 212a, a distance d2 between an edge of the device hole 210 and the adjacent bump electrode 206 is in the range from about 250 micron to about 320 micron, preferably about 280 micron.

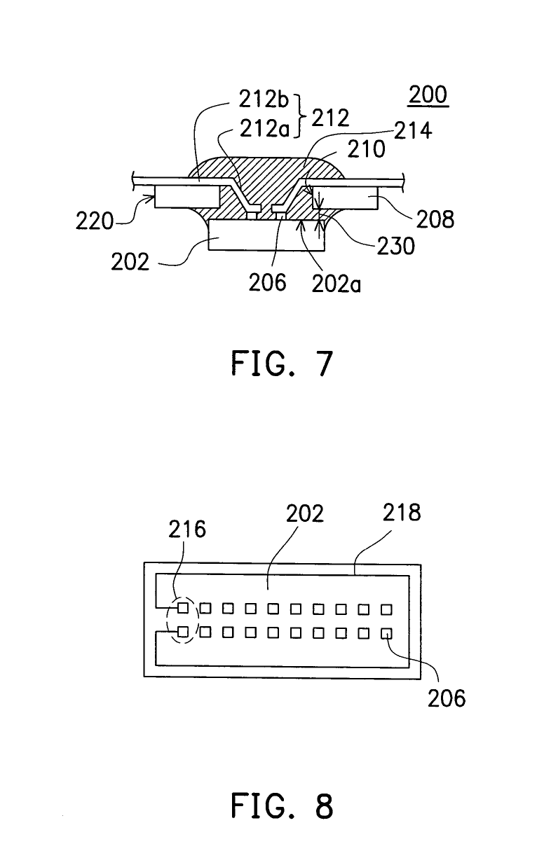

FIG. 7 is a schematic cross sectional view showing that the package of FIG. 4 is sealed. A clearance 230 between the active surface of the chip 202 and the tape carrier 208 is in the range from about 10 to about 60 micron, such that a sealing material 214 can flow out and cover the whole surface of the chip 202 when sealing. Specifically, the sealing material 214 covers the active surface 202a of the chip 202, the inner leads 212a and part of the outer leads 212b, thereby accomplishing a tape carrier package of the present invention.

In the example in which a rectangular chip 202 is used, the length of the device hole 210 is substantially equal to that of the chip 202, and the width of the device hole 210 is smaller than that of chip 202. However, the length and the width of the chip 202 is not limited to the range set forth above, and the chip 202 can have any shape, as long as the bump electrodes 206 are arranged centrally on the active surface 202a of the chip 202 by bump formation process.

With the centrally arranged bump electrodes of the present invention, the bent angle of the inner lead can be reduced, resulting in many advantages over the prior art, such as the area of the device hole can be reduced, the wiring routed area on the tape carrier be increased, the necessary length of the tape carrier be reduced, and thus the cost of final product be lowered. The thus obtained product can meet the commercial requirements of high performance, compact and lightweight.

With the clearance between the active surface of the chip and the tape carrier, the sealing material can be flow out and cover the whole surface of the chip for preventing moisture from entering, resulting in increased reability of the chip.

Second Preferred Embodiment

FIG. 8 is a schematic top view of a chip according to a second preferred embodiment of the present invention.

The bump electrodes 206 are centrally arranged on the chip, as in example 1. a test bump 216 is defined on each end of the two-row of the bump electrodes 206. A test circuit 218 is further defined around the edge of the chip on the active surface 202a. Both ends of the test circuit 218 are electrically connected to two test bumps 206, respectively.

Then, in the thermal pressing process, two of the leads (not shown in this figure) are electrically connected to the two test bumps 206.

A material for the test circuit 218 can be a conductive material, such as polysilicon and metal.

After packaging, an electric test is carried out by connecting the test bumps to the leads to detect whether any defect exists at the edge of the chip, thereby increasing the reliability of the product.

In a light of foregoing, the present invention has advantages over the prior art:

1. By centrally arranging the bump electrodes in two rows, the bent angle of the inner lead routed inward the center of the chip can be reduced, resulting in a decreased area of the device hole. Therefore, the wiring area routed on tape carrier can be increased.

2. Similarly, it is one of characteristics of the present invention that the device hole of the present invention is smaller than a conventional one, such that a desired length of the tape carrier is shorter than the conventional one. Therefor, production cost can be lowered.

3. By providing the test circuit around the edge of the chip and electrically connecting the two test bumps at the both ends of the test circuit, the final product can be subject to the electric test after packaging to examine whether any defect exists at the edge of the chip, thereby increasing the reliability of the product.

It will be apparent to those skilled in the art that various modifications and variations can be made to the structure of the present invention without departing from the scope or spirit of the invention. In view of the forgoing, it is intended that the present invention cover modifications and variations of this invention provided they fall within the scope of the following claims and their equivalents.

What is claimed is:

1. A tape carrier package, comprising:
a chip having an active surface, wherein a plurality of bump electrodes are centrally arranged in two rows on the active surface;
a tape carrier, comprising:
a device hole having an area smaller than the chip; and
a plurality of leads, each of which being divided into inner lead and outer lead, wherein the inner leads are routed inward the center of the device hole and connected to the bump electrodes, respectively;
and
a sealing material encapsulating the active surface of the chip and the inner leads, with the outer leads being exposed.

2. The tape carrier package of claim 1, wherein a distance between the edge of the device hole and the adjacent bump electrodes in the direction of the inner leads are about 280 micron.

3. The tape carrier package of claim 1, wherein the connection between the inner lead and the bump electrode is achieved by thermally pressing.

4. The tape carrier package of claim 1, wherein the bump electrodes are formed by bump formation process.

5. The tape carrier package of claim 1, wherein the chip is a rectangular chip, and the length of the device hole is substantially equal to that of the chip and the width of the device hole is smaller than that of the chip.

6. The tape carrier package of claim 1, further comprising:
two test bumps located at each end of the two rows of the bump electrodes; and
a test circuit around the edge of the chip on the active surface, wherein ends of the test circuit are electrically connected to the test bumps, respectively, and two of the leads are connected to the two test bumps, respectively.

7. The tape carrier package of claim 6, wherein the material of the test circuit includes polysilicon and metal.

8. The tape carrier package of claim 6, wherein the electric test of the chip is achieved by applying current to the test circuit to detect the defect at the edge of the circuit.

9. A chip suitable for detecting edge defects thereof by electrically testing, comprising:
an active surface;
a plurality of bump electrodes centrally arranged in two rows on the active surface;
two test bumps located at each end of the two rows of the bump electrodes; and
a test circuit around the edge of the chip on the active surface, wherein ends of the test circuit are electrically connected to the test bumps, respectively, and two of the leads are connected to the two test bumps, respectively.

10. The tape carrier package of claim 9, wherein the material of the test circuit includes polysilicon ad metal.

11. The tape carrier package of claim 1, further comprising a clearance between the active surface of the chip and the tape carrier, such that the sealing material flows out and cover the whole surface of the chip during sealing.

12. The tape carrier package of claim 11, wherein the clearance is about 10-60 micron.
